(19) United States
(12) Patent Application Publication
(10) Pub. No.: US 2025/0087575 A1
(43) Pub. Date: Mar. 13, 2025

(54) SEMICONDUCTOR DEVICE

(71) Applicant: FUJI ELECTRIC CO., LTD., Kawasaki-shi (JP)

(72) Inventor: Mariko MARUYAMA, Matsumoto-city (JP)

(73) Assignee: FUJI ELECTRIC CO., LTD., Kawasaki-shi (JP)

(21) Appl. No.: 18/782,864

(22) Filed: Jul. 24, 2024

(30) Foreign Application Priority Data
Sep. 13, 2023 (JP) 2023-148512

(51) Int. Cl. H01L 23/498; H01L 23/00; H01L 25/065

(52) U.S. Cl. CPC H01L 23/49844; H01L 23/49822; H01L 23/49833; H01L 24/48; H01L 25/0655; H01L 2224/48137; H01L 2924/12032; H01L 2924/13055; H01L 2924/13091

(57) ABSTRACT

A semiconductor device includes a plurality of semiconductor units connected in parallel to each other; a housing for surrounding the plurality of semiconductor units; a lid disposed on the housing and facing the plurality of semiconductor units; a wiring portion disposed on the lid; and a plurality of connecting portions, each corresponding to one of the plurality of semiconductor units, in which: each of the plurality of semiconductor units includes a first conductor; a semiconductor chip disposed on the first conductor; and a second conductor connected to the semiconductor chip so as to control the semiconductor chip, and a connecting portion that is any one of the plurality of connecting portions is interposed between the wiring portion and a second conductor included in a corresponding semiconductor unit and is electrically connecting the wiring portion to the second conductor included in the corresponding semiconductor unit.

### CROSS REFERENCE TO RELATED APPLICATION

This application is based on, and claims priority from, Japanese Patent Application No. 2023-148512, filed on Sep. 13, 2023, the entire contents of which are incorporated herein by reference.

### BACKGROUND

### Technical Field

This disclosure relates to semiconductor devices.

### Related Art

There have been proposed in the art semiconductor devices including various types of semiconductor chips. For example, Japanese Patent Application Laid-Open Publication No. 2014-112585 discloses a semiconductor device that includes a mounting substrate provided with a semiconductor chip, a housing for accommodating the mounting substrate, and a lid for closing an opening of the housing. The mounting substrate is joined to a connecting member that has an end portion pressed against a circuit pattern disposed on a back surface of the lid. Japanese Patent Application Laid-Open Publication No. 2006-165499 discloses a semiconductor device that includes a power semiconductor element joined to an insulated substrate, a housing for accommodating the power semiconductor element, and a cover for closing an opening of the housing. This semiconductor device is provided with a plurality of spring terminals that penetrate through the cover to extend outside the housing. To control a large current, a semiconductor device is proposed in which a plurality of semiconductor units including semiconductor chips are connected in parallel to each other. In the above configuration, it is necessary to provide each of the plurality of semiconductor units with a conductive pattern for electrically connecting control electrodes of the semiconductor chips included in the plurality of semiconductor units to each other. Thus, there is a disadvantage of limiting size reduction of each of the plurality of semiconductor units.

### SUMMARY

An object of one aspect according to this disclosure is to reduce a planar size of each semiconductor unit of a plurality of semiconductor units that are connected in parallel to each other.

A semiconductor device according to one aspect of this disclosure includes a plurality of semiconductor units connected in parallel to each other; a housing for surrounding the plurality of semiconductor units; a lid disposed on the housing, the lid facing the plurality of semiconductor units; a wiring portion disposed on the lid; and a plurality of connecting portions, each corresponding to a semiconductor unit of the plurality of semiconductor units, in which each of the plurality of semiconductor units includes a first conductor; a semiconductor chip disposed on the first conductor; and a second conductor connected to the semiconductor chip so as to control the semiconductor chip, and in which a connecting portion that is any one of the plurality of connecting portions is interposed between the wiring portion and a second conductor included in a semiconductor unit corresponding to the connecting portion among the plurality of semiconductor units, the connecting portion electrically connecting the wiring portion and the second conductor included in the semiconductor unit corresponding to the connecting portion to each other.

### BRIEF DESCRIPTION OF THE DRAWINGS

FIG. 1 is a plan view of a semiconductor device according to a First Embodiment.

FIG. 2 is a plan view of the semiconductor device according to the First Embodiment.

FIG. 3 is a plan view of a semiconductor unit.

FIG. 4 is a plan view of a wiring substrate.

FIG. 5 is a cross section taken along line V-V shown in FIG. 4.

FIG. 6 is a plan view of a wiring substrate.

FIG. 7 is a cross section taken along line VII-VII shown in FIG. 6.

FIG. 8 is a side view of a connecting portion.

FIG. 9 is a plan view of a semiconductor device according to a Comparative Example.

FIG. 10 is a plan view of a wiring substrate according to a Second Embodiment.

FIG. 11 is a plan view of a wiring substrate according to the Second Embodiment.

FIG. 12 is a plan view of conductive members according to a Third Embodiment.

FIG. 13 is a cross section taken along line XIII-XIII shown in FIG. 12.

FIG. 14 is a plan view of conductive members according to the Third Embodiment.

FIG. 15 is a cross section taken along line XV-XV shown in FIG. 14.

FIG. 16 is a side view of a connecting portion according to a modification.

FIG. 17 is a side view of a connecting portion according to another modification.

### DESCRIPTION OF EMBODIMENTS

Embodiments according to this disclosure will now be described with reference to the accompanying drawings. In each drawing, dimensions and scales of elements may differ from those of actual products. In addition, each embodiment described below is an exemplary embodiment assumed in a case in which this disclosure is implemented. Thus, the scope of this disclosure is not limited to the embodiments described below.

### A: First Embodiment

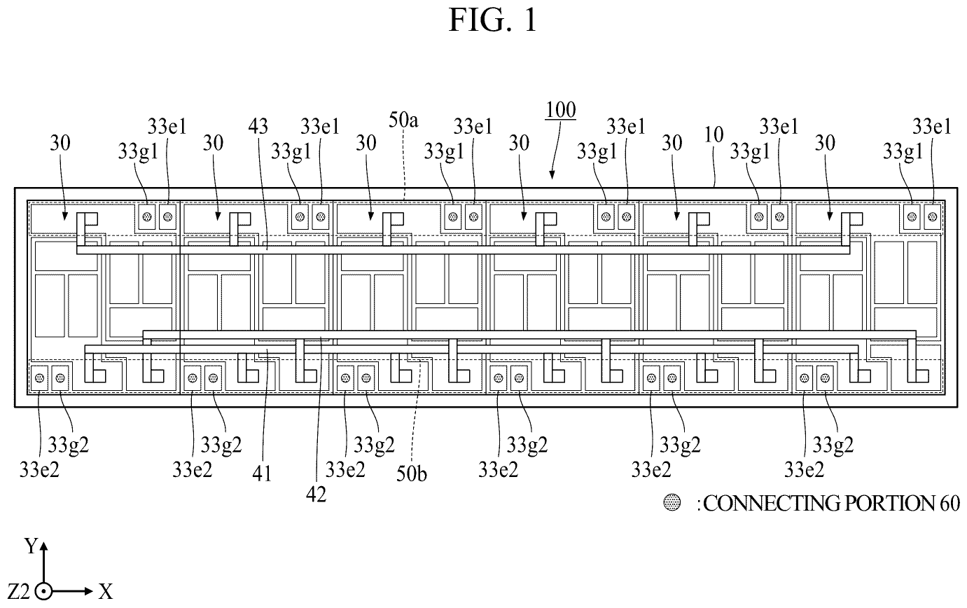

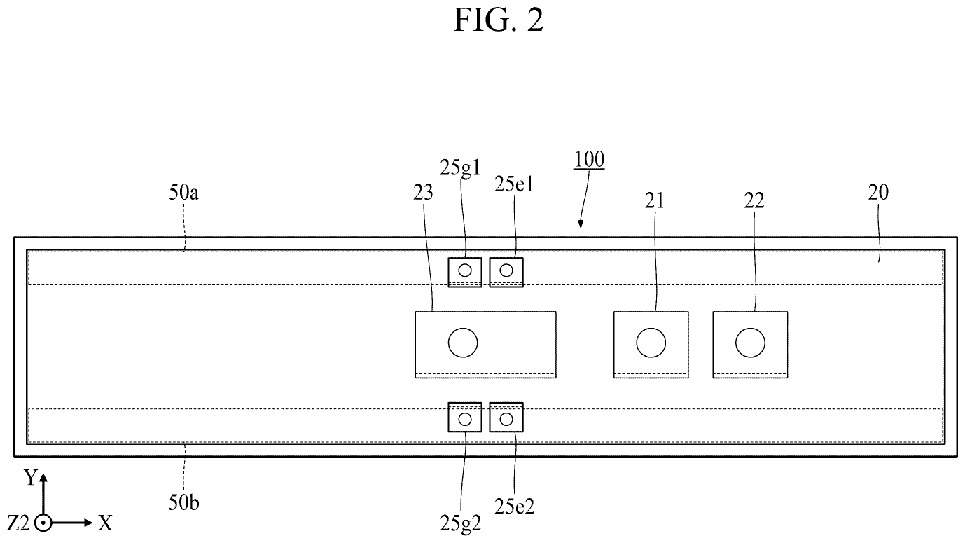

FIG. 1 and FIG. 2 are each a plan view of a semiconductor device 100 according to a First Embodiment of this disclosure. The semiconductor device 100 according to the First Embodiment is, for example, a power semiconductor module included in an inverter circuit of a power conversion apparatus.

In the following description, an X-axis, a Y-axis, and a Z-axis are assumed that are perpendicular to one another. A direction along the Z-axis is referred to as direction Z1, and a direction opposite to the direction Z1 is referred to as direction Z2. In actual use, the semiconductor device 100 may be disposed in any direction. However, in the following description, for convenience, the direction Z1 is assumed to be a downward direction, and the direction Z2 is assumed to be an upward direction. Thus, a surface facing in the direction Z1 among a plurality of surfaces of the semiconductor device 100 may be referred to as a “lower surface,” and a surface facing in the direction Z2 among the plurality of surfaces of the semiconductor device 100 may be referred to as an “upper surface.” In the following description, a view of a target in a direction along the Z-axis is referred to as a “plan view.”

In the First Embodiment, the semiconductor device 100 includes a housing 10, a lid 20, and six semiconductor units 30. In FIG. 1, the lid 20 is omitted for convenience. The number of semiconductor units 30 included in the semiconductor device 100 is not limited to six and may be changed as appropriate.

The housing 10 is a rectangular frame-shaped structure for housing and surrounding the six semiconductor units 30. The six semiconductor units 30 are accommodated in the housing 10 to be aligned with one another in a direction of the X-axis. The six semiconductor units 30 are connected in parallel to one another.

In FIG. 2, the lid 20 is a flat plate-shaped structure for closing an opening of the housing 10. The lid 20 is disposed on the housing 10. Specifically, a plurality of side surfaces of the lid 20 are bonded by, for example, an adhesive, to a plurality of inner wall surfaces of the housing 10. In a state in which the housing 10 is provided with the lid 20, the lid 20 faces the six semiconductor units 30. In other words, in plan view, the lid 20 overlaps with the six semiconductor units 30.

The housing 10 and the lid 20 are each made of an insulated resin material such as a polyphenylene sulfide (PPS) resin material, a polybutylene terephthalate (PBT) resin material, a polybutylene succinate (PBS) resin material, a polyamide (PA) resin material, or an acrylonitrile-butadiene-styrene (ABS) resin material, for example.

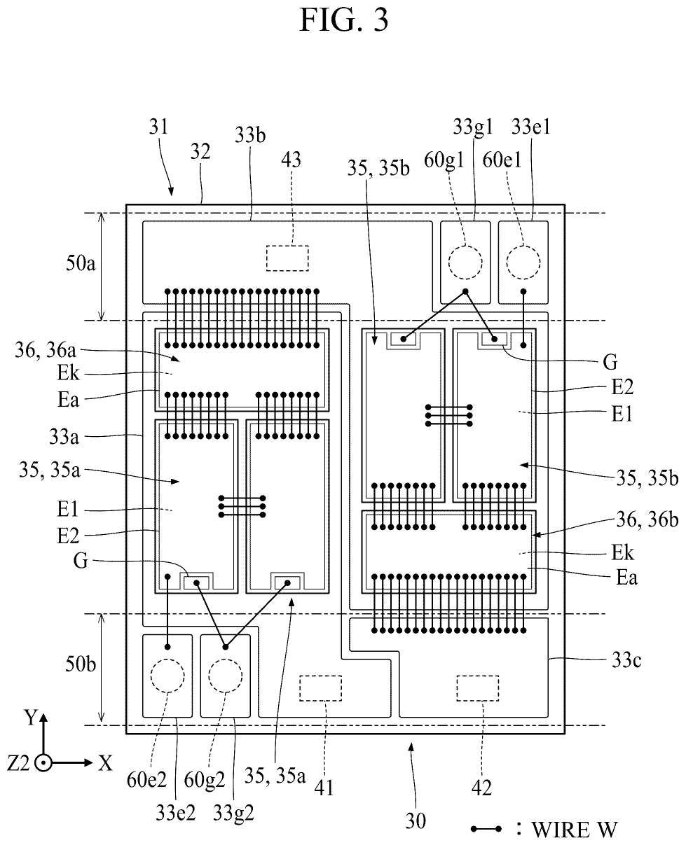

FIG. 3 is a plan view of a configuration of a semiconductor unit 30 of the six semiconductor units 30. The six semiconductor units 30 have the same configuration. As shown in FIG. 3, each of the six semiconductor units 30 includes a mounting substrate 31, four semiconductor chips 35, and two semiconductor chips 36.

The mounting substrate 31 is a wiring substrate provided with the four semiconductor chips 35 and the two semiconductor chips 36. The mounting substrate 31 is a substrate such as a direct copper bonding (DCB) substrate, an active metal brazing (AMB) substrate, or an insulated metal substrate (IMS).

The mounting substrate 31 is constituted of a stack of an insulated substrate 32 and a plurality of conductive patterns 33 (33a, 33b, 33c, 33g1, 33e1, 33g2, and 33e2). The insulated substrate 32 is a rectangular plate-shaped member made of an insulating material. The insulated substrate 32 is made of a ceramic material such as aluminum oxide, aluminum nitride, or silicon nitride, for example. Alternatively, the insulated substrate 32 may be made of a resin material such as an epoxy resin material. The mounting substrate 31 includes a lower surface provided with a heat radiating plate (not shown) made of a metallic material with high thermal conductivity such as a copper material. In the First Embodiment, a configuration is described in which the insulated substrate 32 is provided for each of the six semiconductor units 30. However, the insulated substrate 32 may be a single member provided with the six semiconductor units 30.

Each of the plurality of conductive patterns 33 is a thin plate-shaped conductor disposed on an upper surface of the insulated substrate 32. Each of the plurality of conductive patterns 33 is made of a low-resistance conductive material such as a copper material or an alloy of copper. In the First Embodiment, the plurality of conductive patterns 33 include a conductive pattern 33a, a conductive pattern 33b, a conductive pattern 33c, a conductive pattern 33g1, a conductive pattern 33e1, a conductive pattern 33g2, and a conductive pattern 33e2.

The conductive pattern 33g1 and the conductive pattern 33e1 are disposed apart from the conductive pattern 33a across the conductive pattern 33b. In other words, the conductive pattern 33b is interposed between the conductive pattern 33a and a combination of the conductive pattern 33g1 and the conductive pattern 33e1. The conductive pattern 33g2 and the conductive pattern 33e2 are disposed apart from the conductive pattern 33b across the conductive pattern 33a. In other words, the conductive pattern 33a is interposed between the conductive pattern 33b and a combination of the conductive pattern 33g2 and the conductive pattern 33e2. As will be understood from the above description, in plan view, the combination of the conductive pattern 33g1 and the conductive pattern 33e1 is disposed at one diagonal corner of a pair of diagonal corners of the rectangular semiconductor unit 30, and the combination of the conductive pattern 33g2 and the conductive pattern 33e2 is disposed at the other diagonal corner of the pair of diagonal corners of the rectangular semiconductor unit 30.

Thus, as shown in FIG. 1, combinations of the conductive pattern 33g1 and the conductive pattern 33e1 included in the six semiconductor units 30 are aligned with one another in the direction of the X-axis. Similarly, combinations of the conductive pattern 33g2 and the conductive pattern 33e2 included in the six semiconductor units 30 are aligned with one another in the direction of the X-axis. An arrangement of the combinations of the conductive pattern 33g1 and the conductive pattern 33e1 and an arrangement of the combinations of the conductive pattern 33g2 and the conductive pattern 33e2 extend in parallel to each other in the direction of the X-axis to be spaced apart from each other in a direction of the Y-axis.

As shown in FIG. 1 and FIG. 3, the conductive pattern 33a of each of the six semiconductor units 30 is connected to a wiring member 41. The conductive pattern 33c of each of the six semiconductor units 30 is connected to a wiring member 42. The conductive pattern 33b of each of the six semiconductor units 30 is connected to a wiring member 43. The wiring member 43 is a line for outputting power. The wiring member 41, the wiring member 42, and the wiring member 43 are each a conductor (for example, a lead frame) extending in the direction of the X-axis in a space between the lid 20 and each of the six semiconductor units 30.

As shown in FIG. 2, an upper surface of the lid 20 is provided with a positive electrode terminal 21, a negative electrode terminal 22, and an output terminal 23. The positive electrode terminal 21 (P terminal) is connected to the wiring member 41. A power supply voltage of a high potential side is supplied to the positive electrode terminal 21. In other words, the power supply voltage of the high potential side is supplied to the conductive pattern 33a of each of the six semiconductor units 30 via the positive electrode terminal 21 and the wiring member 41. The negative electrode terminal 22 (N terminal) is connected to the wiring member 42. A power supply voltage of a low potential side is supplied to the negative electrode terminal 22. In other words, the power supply voltage of the low potential side is supplied to the conductive pattern 33c of each of the six semiconductor units 30 via the negative electrode terminal 22 and the wiring member 42. The output terminal 23 is connected to the wiring member 43. In other words, AC power dependent on operation of each of the six semiconductor units 30 is output from the output terminal 23.

In FIG. 3, each of the four semiconductor chips 35 is a semiconductor chip 35 that is a power semiconductor element disposed on the mounting substrate 31. The semiconductor chip 35 functions as a switching element that can switch between flow of electricity and interruption of electricity. In this embodiment, the semiconductor chip 35 is an insulated gate bipolar transistor (IGBT), for example. The semiconductor chip 35 is bonded by a joining material such as solder or a sintered material to one of the plurality of conductive patterns 33.

The semiconductor chip 35 includes a first electrode E1, a second electrode E2, and a control electrode G. The first electrode E1 and the second electrode E2 are main electrodes configured to receive and output a current as a control target. The first electrode E1 is a collector electrode that constitutes a lower surface of the semiconductor chip 35. The first electrode E1 further functions as a cathode of a freewheeling diode (FWD). The first electrode E1 of each of the four semiconductor chips 35 is joined to one of the plurality of conductive patterns 33. The second electrode E2 is an emitter electrode that constitutes an upper surface of the semiconductor chip 35. The second electrode E2 further functions as an anode of the FWD. The control electrode G is a gate electrode to which a control voltage is applied for control to turn the semiconductor chip 35 on and off. The control electrode G, together with the second electrode E2, constitutes the upper surface of the semiconductor chip 35.

Each of the two semiconductor chips 36 is a semiconductor chip 36 that is an FWD including an anode Ea and a cathode Ek. The anode Ea constitutes an upper surface of the semiconductor chip 36, and the cathode Ek constitutes a lower surface of the semiconductor chip 36.

The four semiconductor chips 35, which are included in a semiconductor unit 30, are divided into two semiconductor chips 35a and two semiconductor chips 35b. The two semiconductor chips 36, which are included in the semiconductor unit 30, are divided into a semiconductor chip 36a and a semiconductor chip 36b. The two semiconductor chips 35a and the semiconductor chip 36a constitute an upper arm of an inverter circuit, and the two semiconductor chips 35b and the semiconductor chip 36b constitute a lower arm of the inverter circuit.

The two semiconductor chips 35a and the semiconductor chip 36a are joined to the conductive pattern 33a. The conductive pattern 33a provided with the two semiconductor chips 35a is an example of a “first conductor.” Control electrodes G of the two semiconductor chips 35a are connected by wires W (bonding wires) to each other, for example. Second electrodes E2 of the two semiconductor chips 35a are connected by wires W to an anode Ea of the semiconductor chip 36a. The anode Ea of the semiconductor chip 36a is connected by wires W to the conductive pattern 33b. In other words, the two semiconductor chips 35a are connected in parallel to each other.

The conductive pattern 33g2 is connected by a wire W to the control electrode G of each of the two semiconductor chips 35a, for example. In other words, the conductive pattern 33g2 is electrically connected to the control electrode G of each of the two semiconductor chips 35a. The conductive pattern 33e2 is connected by a wire W to the second electrode E2 of each of the two semiconductor chips 35a, for example. In other words, the conductive pattern 33e2 is electrically connected to the second electrode E2 of each of the two semiconductor chips 35a.

The conductive pattern 33g1 is connected by a wire W to the control electrode G of each of the two semiconductor chips 35b, for example. In other words, the conductive pattern 33g1 is electrically connected to the control electrode G of each of the two semiconductor chips 35b. The conductive pattern 33e1 is connected by a wire W to the second electrode E2 of each of the two semiconductor chips 35b, for example. In other words, the conductive pattern 33e1 is electrically connected to the second electrode E2 of each of the two semiconductor chips 35b.

The conductive pattern 33g1 is a control terminal connected to the control electrode G of each of the two semiconductor chips 35b so as to control the two semiconductor chips 35b. The conductive pattern 33g2 is a control terminal connected to the control electrode G of each of the two semiconductor chips 35a so as to control the two semiconductor chips 35a. The conductive pattern 33g1 and the conductive pattern 33g2 are each an example of a “first conductive pattern.” The conductive pattern 33e1 is an auxiliary terminal connected to the second electrodes E2 of the two semiconductor chips 35b. The conductive pattern 33e2 is an auxiliary terminal connected to the second electrodes E2 of the two semiconductor chips 35a. Specifically, the conductive pattern 33e1 is an auxiliary emitter terminal for accurately controlling voltage between the control electrode G and the second electrode E2 that are included in each of the two semiconductor chips 35b. The conductive pattern 33e2 is an auxiliary emitter terminal for accurately controlling voltage between the control electrode G and the second electrode E2 that are included in each of the two semiconductor chips 35a. The conductive pattern 33e1 and the conductive pattern 33e2 are each an example of a “second conductive pattern.” As will be understood from the above description, the conductive pattern 33g1, the conductive pattern 33g2, the conductive pattern 33e1, and the conductive pattern 33e2 are each a conductor connected to semiconductor chips 35 so as to control the semiconductor chips 35 and are each an example of a “second conductor.”

As shown in FIG. 1 to FIG. 3, the semiconductor device 100 according to the First Embodiment includes a wiring substrate 50a and a wiring substrate 50b. The wiring substrate 50a is a circuit substrate for interconnecting conductive patterns 33g1 included in the six semiconductor units 30 and for interconnecting conductive patterns 33e1 included in the six semiconductor units 30. The wiring substrate 50b is a circuit substrate for interconnecting conductive patterns 33g2 included in the six semiconductor units 30 and for interconnecting conductive patterns 33e2 included in the six semiconductor units 30.

The wiring substrate 50a and the wiring substrate 50b are disposed on the lid 20. Specifically, a lower surface of the lid 20 (a surface in the direction Z1) is provided with the wiring substrate 50a and the wiring substrate 50b. Thus, in plan view, the wiring substrate 50a and the wiring substrate 50b overlap with the mounting substrate 31 of each of the six semiconductor units 30. The wiring substrate 50a and the wiring substrate 50b are bonded by an adhesive to the lower surface of the lid 20, for example. Alternatively, the wiring substrate 50a and the wiring substrate 50b may be fixed by fasteners, such as screws, to the lid 20, for example.

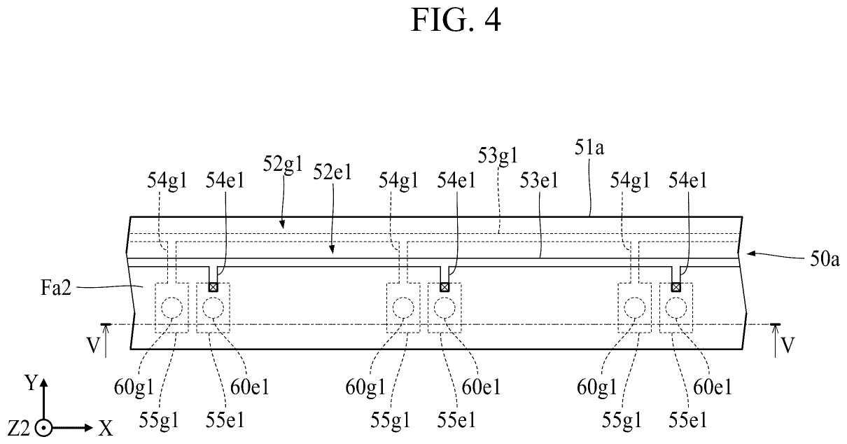

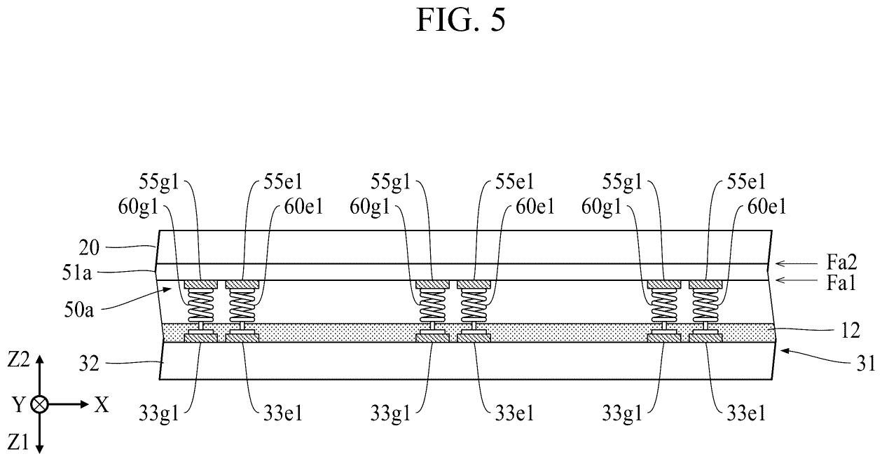

FIG. 4 is a plan view of the wiring substrate 50a. FIG. 5 is a cross section taken along line V-V shown in FIG. 4. In FIG. 5, the lid 20 and the mounting substrate 31, together with the wiring substrate 50a, are shown.

As shown in FIG. 4 and FIG. 5, the wiring substrate 50a includes an insulated substrate 51a, a line 52g1, and a line 52e1. The insulated substrate 51a is an insulated plate-shaped member made of a resin material such as an epoxy-based resin material, for example. The insulated substrate 51a includes a first surface Fa1 and a second surface Fa2. In the insulated substrate 51a, the first surface Fa1 and the second surface Fa2 oppose each other. Specifically, the first surface Fa1 is a lower surface facing a direction (the direction Z1) opposite to a direction toward the lid 20, and the second surface Fa2 is an upper surface facing the lower surface of the lid 20.

The line 52g1 and the line 52e1 are each a conductor disposed on the insulated substrate 51a. As described above, the insulated substrate 51a is disposed on the lid 20. Thus, the lid 20 is provided with the line 52g1 and the line 52e1 via the insulated substrate 51a. A combination of the line 52g1 and the line 52e1 is an example of a “wiring portion.” In other words, the “wiring portion” includes the line 52g1 and the line 52e1.

The line 52g1 is a conductor for interconnecting six conductive patterns 33g1 included in the six semiconductor units 30. The line 52g1 is an example of a “first line.” The line 52g1 is disposed on the first surface Fa1 of the insulated substrate 51a. As shown in FIG. 4, the line 52g1 according to the First Embodiment is a conductive pattern that includes an extending portion 53g1, six branch portions 54g1, and six connecting terminals 55g1.

The extending portion 53g1 is a portion that extends linearly in the direction of the X-axis in which the six semiconductor units 30 are aligned with one another. The extending portion 53g1 is an example of a “first extending portion.” The six connecting terminals 55g1 are aligned with, and are spaced apart from, one another in the direction of the X-axis along the extending portion 53g1. Each of the six branch portions 54g1 is a portion that extends from the extending portion 53g1 in a direction along the Y-axis toward a corresponding connecting terminal 55g1 among the six connecting terminals 55g1. One end of each of the six branch portions 54g1 is coupled to the corresponding connecting terminal 55g1.

The line 52e1 is a conductor for interconnecting six conductive patterns 33e1 included in the six semiconductor units 30. The line 52e1 is an example of a “second line.”. As shown in FIG. 4, the line 52e1 according to the First Embodiment is a conductive pattern that includes an extending portion 53e1, six branch portions 54e1, and six connecting terminals 55e1. The six connecting terminals 55e1 are disposed on the first surface Fa1 of the insulated substrate 51a, and the extending portion 53e1 and the six branch portions 54e1 are disposed on the second surface Fa2 of the insulated substrate 51a. In other words, the extending portion 53g1 is disposed on the first surface Fa1, and the extending portion 53e1 is disposed on the second surface Fa2.

The extending portion 53e1 is a portion that extends linearly in the direction of the X-axis in which the six semiconductor units 30 are aligned with one another. The extending portion 53e1 is an example of a “second extending portion.” The six connecting terminals 55e1 are aligned with, and are spaced apart from, one another in the direction of the X-axis along the extending portion 53e1. Each of the six branch portions 54e1 is a portion that extends from the extending portion 53e1 in the direction along the Y-axis toward a corresponding connecting terminal 55e1 among the six connecting terminals 55e1. One end of each of the six branch portions 54e1 is electrically connected to the corresponding connecting terminal 55e1 by a via hole included in the insulated substrate 51a.

As shown in FIG. 5, the connecting terminals 55g1 of the wiring substrate 50a and the conductive patterns 33g1 of the six semiconductor units 30 face each other. The conductive pattern 33g1, which is each of the conductive patterns 33g1, is electrically connected to a corresponding connecting terminal 55g1 among the connecting terminals 55g1 via a connecting portion 60g1. The connecting portion 60g1 is a conductor interposed between the conductive pattern 33g1 and the connecting terminal 55g1. The connecting portion 60g1 is disposed to correspond to one of the six semiconductor units 30. In other words, the connecting portion 60g1 electrically connects the conductive pattern 33g1 of a corresponding semiconductor unit 30 to the line 52g1 of the wiring substrate 50a. As described above, according to the First Embodiment, it is possible to electrically connect the control electrode G of the semiconductor chip 35b of each of the six semiconductor units 30 to the line 52g1 via the conductive pattern 33g1 and the connecting portion 60g1.

Similarly, the connecting terminals 55e1 of the wiring substrate 50a and the conductive patterns 33e1 of the six semiconductor units 30 face each other. The conductive pattern 33e1, which is each of the conductive patterns 33e1, is electrically connected to a corresponding connecting terminal 55e1 among the connecting terminals 55e1 via a connecting portion 60e1. The connecting portion 60e1 is a conductor interposed between the conductive pattern 33e1 and the connecting terminal 55e1. The connecting portion 60e1 is disposed to correspond to one of the six semiconductor units 30. In other words, the connecting portion 60e1 electrically connects the conductive pattern 33e1 of a corresponding semiconductor unit 30 to the line 52e1 of the wiring substrate 50a. As described above, according to the First Embodiment, it is possible to electrically connect the second electrode E2 of the semiconductor chip 35b of each of the six semiconductor units 30 to the line 52e1 via the conductive pattern 33e1 and the connecting portion 60e1.

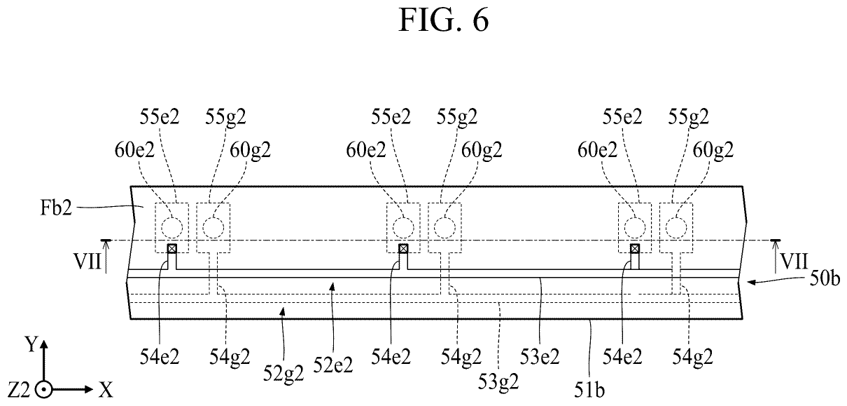

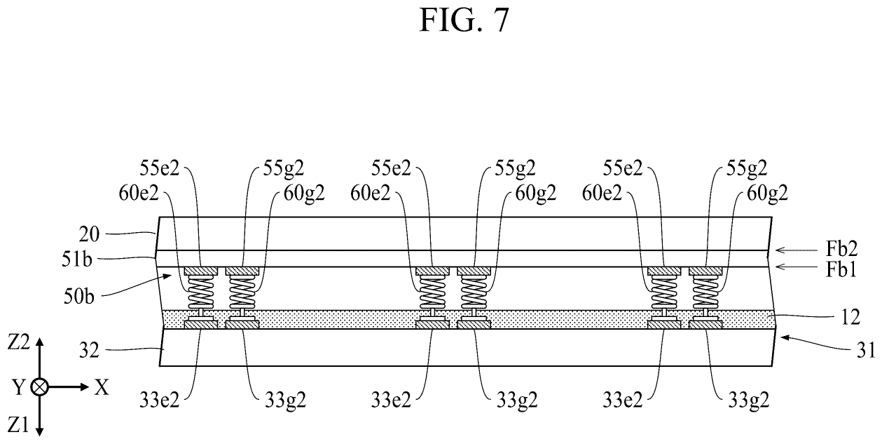

FIG. 6 is a plan view of the wiring substrate 50b. FIG. 7 is a cross section taken along line VII-VII shown in FIG. 6. In FIG. 7, the lid 20 and the mounting substrate 31, together with the wiring substrate 50b, are shown.

As shown in FIG. 6 and FIG. 7, the wiring substrate 50b includes an insulated substrate 51b, a line 52g2, and a line 52e2. The insulated substrate 51b, as well as the insulated substrate 51a, is an insulated plate-shaped member. The insulated substrate 51b includes a first surface Fb1 and a second surface Fb2 that are opposite to each other.

The line 52g2 and the line 52e2 are each a conductor disposed on the insulated substrate 51b. In other words, the lid 20 is provided with the line 52g2 and the line 52e2 via the insulated substrate 51b. A combination of the line 52g2 and the line 52e2 is an example of the “wiring portion.”

The line 52g2 is a conductor for interconnecting six conductive patterns 33g2 included in the six semiconductor units 30. The line 52g2 is an example of the “first line.” The line 52g2 is disposed on the first surface Fb1 of the insulated substrate 51b. As shown in FIG. 6, the line 52g2 according to the First Embodiment is a conductive pattern that includes an extending portion 53g2, six branch portions 54g2, and six connecting terminals 55g2.

The extending portion 53g2 is a portion that extends linearly in the direction of the X-axis in which the six semiconductor units 30 are aligned with one another. The extending portion 53g2 is an example of the “first extending portion.” The six connecting terminals 55g2 are aligned with, and are spaced apart from, one another in the direction of the X-axis along the extending portion 53g2. Each of the six branch portions 54g2 is a portion that extends from the extending portion 53g2 in a direction along the Y-axis toward a corresponding connecting terminal 55g2 among the six connecting terminals 55g2. One end of each of the six branch portions 54g2 is coupled to the corresponding connecting terminal 55g2.

The line 52e2 is a conductor for interconnecting six conductive patterns 33e2 included in the six semiconductor units 30. The line 52e2 is an example of the “second line.” As shown in FIG. 6, the line 52e2 according to the First Embodiment is a conductive pattern that includes an extending portion 53e2, six branch portions 54e2, and six connecting terminals 55e2. The six connecting terminals 55e2 are disposed on the first surface Fb1 of the insulated substrate 51b, and the extending portion 53e2 and the six branch portions 54e2 are disposed on the second surface Fb2 of the insulated substrate 51b. In other words, the extending portion 53g2 is disposed on the first surface Fb1, and the extending portion 53e2 is disposed on the second surface Fb2.

The extending portion 53e2 is a portion that extends linearly in the direction of the X-axis in which the six semiconductor units 30 are aligned with one another. The extending portion 53e2 is an example of the “second extending portion.” The six connecting terminals 55e2 are aligned with, and are spaced apart from, one another in the direction of the X-axis along the extending portion 53e2. Each of the six branch portions 54e2 is a portion that extends from the extending portion 53e2 in the direction along the Y-axis toward a corresponding connecting terminal 55e2 among the six connecting terminals 55e2. One end of each of the six branch portions 54e2 is electrically connected to the corresponding connecting terminal 55e2 by a via hole included in the insulated substrate 51b.

As shown in FIG. 7, the connecting terminals 55g2 of the wiring substrate 50b and the conductive patterns 33g2 of the six semiconductor units 30 face each other. The conductive pattern 33g2, which is each of the conductive patterns 33g2, is electrically connected to a corresponding connecting terminal 55g2 among the connecting terminals 55g2 via a connecting portion 60g2. The connecting portion 60g2 is a conductor interposed between the conductive pattern 33g2 and the connecting terminal 55g2. The connecting portion 60g2 is disposed to correspond to one of the six semiconductor units 30. In other words, the connecting portion 60g2 electrically connects the conductive pattern 33g2 of a corresponding semiconductor unit 30 to the line 52g2 of the wiring substrate 50b. As described above, according to the First Embodiment, it is possible to electrically connect the control electrode G of the semiconductor chip 35a of each of the six semiconductor units 30 to the line 52g2 via the conductive pattern 33g2 and the connecting portion 60g2.

Similarly, the connecting terminals 55e2 of the wiring substrate 50b and the conductive patterns 33e2 of the six semiconductor units 30 face each other. The conductive pattern 33e2, which is each of the conductive patterns 33e2, is electrically connected to a corresponding connecting terminal 55e2 among the connecting terminals 55e2 via a connecting portion 60e2. The connecting portion 60e2 is a conductor interposed between the conductive pattern 33e2 and the connecting terminal 55e2. The connecting portion 60e2 is disposed to correspond to one of the six semiconductor units 30. In other words, the connecting portion 60e2 electrically connects the conductive pattern 33e2 of a corresponding semiconductor unit 30 to the line 52e2 of the wiring substrate 50b. As described above, according to the First Embodiment, it is possible to electrically connect the second electrode E2 of the semiconductor chip 35a of each of the six semiconductor units 30 to the line 52e2 via the conductive pattern 33e2 and the connecting portion 60e2.

As shown in FIG. 5 and FIG. 7, an encapsulant 12 is disposed in a space inside the housing 10. The encapsulant 12 is made of a resin material for encapsulating each of the six semiconductor units 30. The encapsulant 12 may be made of a resin material such as an epoxy resin material or a phenol resin material, for example. Alternatively, the encapsulant 12 may be made of silicone gel. The encapsulant 12 may include fillers that may be made of a silicon oxide material or that may be made of an aluminum oxide material, for example. The connecting portion 60g1, the connecting portion 60g2, the connecting portion 60e1, and the connecting portion 60e2 are each a connecting portion 60. As shown in FIG. 5 and FIG. 7, the encapsulant 12 covers a part of the connecting portion 60.

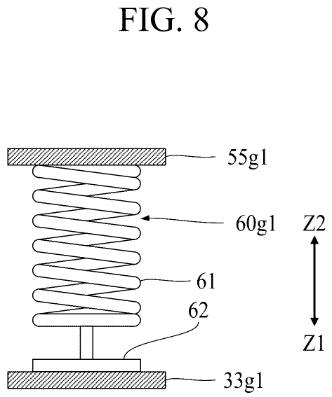

FIG. 8 is a side view of the connecting portion 60. In FIG. 8, for convenience, the connecting portion 60g1 is shown. Connecting portions 60 (60e1, 60g2, and 60e2) other than the connecting portion 60g1 each have the same configuration as the connecting portion 60g1.

As shown in FIG. 8, the connecting portion 60g1 is a conductor that includes an elastic body 61 and a terminal portion 62. The elastic body 61 and the terminal portion 62 are integrally formed of a low-resistance conductive material such as a copper material or an alloy of copper. The elastic body 61 is an elastically deformable structure. Specifically, the elastic body 61 is a coil spring that can be elastically compressed. The terminal portion 62 is a terminal connected to a lower end of the elastic body 61. The terminal portion 62 is bonded by a joining material such as solder or a sintered material to a corresponding conductive pattern 33g1. In other words, the connecting portion 60g1 protrudes in the direction Z2 from an upper surface of a corresponding mounting substrate 31.

An upper end of the elastic body 61 is in contact with a corresponding connecting terminal 55g1 of the line 52g1 of the wiring substrate 50a. Specifically, the connecting portion 60g1 is disposed between a corresponding semiconductor unit 30 and the lid 20 in a state in which the elastic body 61 is sandwiched between the corresponding conductive pattern 33g1 and the corresponding connecting terminal 55g1 (line 52g1) and is compressed. In other words, the elastic body 61 of the connecting portion 60g1 is compressed to be disposed between the corresponding conductive pattern 33g1 and the corresponding connecting terminal 55g1. As will be understood from the above description, the upper end of the elastic body 61 is pressed against the corresponding connecting terminal 55g1.

According to the above configuration, in a simple step in which the lid 20 compresses the elastic body 61 in the course of disposing the lid 20 on the housing 10, the connecting portion 60g1 can reliably electrically connect the corresponding conductive pattern 33g1 and the line 52g1 to each other.

In the above description, the connecting portion 60g1 disposed between the corresponding conductive pattern 33g1 and the corresponding connecting terminal 55g1 is focused on. Each of the connecting portions 60 (60e1, 60g2, and 60e2), other than the connecting portion 60g1, is disposed in substantially the same manner as the connecting portion 60g1. Specifically, the connecting portion 60e1 is disposed between a corresponding conductive pattern 33e1 and a corresponding connecting terminal 55e1 in a state in which an elastic body 61 of the connecting portion 60e1 is compressed. The connecting portion 60g2 is disposed between a corresponding conductive pattern 33g2 and a corresponding connecting terminal 55g2 in a state in which an elastic body 61 of the connecting portion 60g2 is compressed. The connecting portion 60e2 is disposed between a corresponding conductive pattern 33e2 and a corresponding connecting terminal 55e2 in a state in which an elastic body 61 of the connecting portion 60e2 is compressed.

As shown in FIG. 2, the upper surface of the lid 20 is provided with a control terminal 25g1, a control terminal 25e1, a control terminal 25g2, and a control terminal 25e2. The control terminal 25g1 is connected to the line 52g1 of the wiring substrate 50a, and the control terminal 25e1 is connected to the line 52e1 of the wiring substrate 50a. The control terminal 25g2 is connected to the line 52g2 of the wiring substrate 50b, and the control terminal 25e2 is connected to the line 52e2 of the wiring substrate 50b.

As shown in FIG. 2, the control terminal 25g1 and the control terminal 25e1 are disposed on a middle portion of the lid 20 in the direction of the X-axis. Similarly, the control terminal 25g2 and the control terminal 25e2 are disposed on the middle portion of the lid 20 in the direction of the X-axis. The positive electrode terminal 21, the negative electrode terminal 22, and the output terminal 23 are disposed in a portion of the lid 20 that extends in the direction of the X-axis and that is interposed between a combination of the control terminal 25g1 and the control terminal 25e1 and a combination of the control terminal 25g2 and the control terminal 25e2.

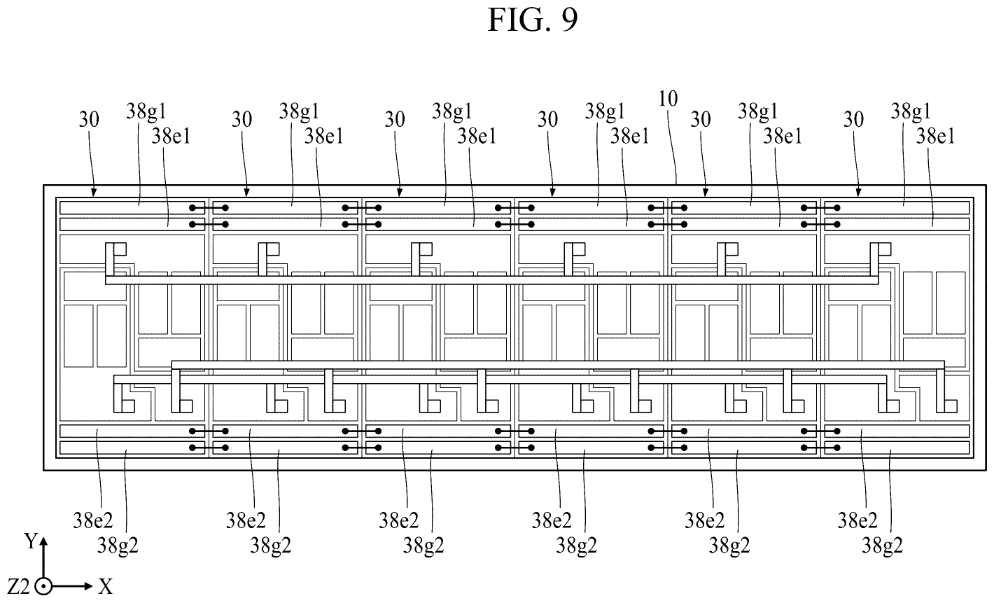

A configuration shown in FIG. 9 (hereinafter referred to as a “Comparative Example”) is assumed to be a configuration in which the six semiconductor units 30 are connected in parallel to one another. In the Comparative Example, the mounting substrate 31 of each of the six semiconductor units 30 is provided with a plurality of relay patterns 38 constituted of a relay pattern 38g1, a relay pattern 38e1, a relay pattern 38g2, and a relay pattern 38e2.

The relay pattern 38g1 is connected to the control electrodes G of the two semiconductor chips 35b included in a semiconductor unit 30 including the relay pattern 38g1. Relay patterns 38g1 of the six semiconductor units 30 are connected by wires W to one another. The relay pattern 38e1 is connected to the second electrodes E2 of the two semiconductor chips 35b included in the semiconductor unit 30. Relay patterns 38e1 of the six semiconductor units 30 are connected by wires W to one another.

Similarly, the relay pattern 38g2 is connected to the control electrodes G of the two semiconductor chips 35a included in the semiconductor unit 30. Relay patterns 38g2 of the six semiconductor units 30 are connected by wires W to one another. The relay pattern 38e2 is connected to the second electrodes E2 of the two semiconductor chips 35a included in the semiconductor unit 30. Relay patterns 38e2 of the six semiconductor units 30 are connected by wires W to one another.

As described above, in the Comparative Example, the mounting substrate 31 of each of the six semiconductor units 30 needs to be provided with the plurality of relay patterns 38 (38g1, 38e1, 38g2, and 38e2). Thus, there is a disadvantage of limiting size reduction of each of the six of semiconductor units 30. In particular, in the Comparative Example, it is difficult to reduce a size of each of the six semiconductor units 30 in the direction of the Y-axis.

In contrast to the Comparative Example, in the First Embodiment, the conductive patterns 33 (33g1, 33e1, 33g2, and 33e2) of each of the six semiconductor units 30 are electrically connected to a plurality of lines 52 constituted of the line 52g1, the line 52e1, the line 52g2, and the line 52e2, which are disposed on the lid 20. Thus, compared to the Comparative Example in which each of the six semiconductor units 30 is provided with the relay patterns 38 connected to other relay patterns 38, it is possible to reduce a planar size of each of the six semiconductor units 30. In the First Embodiment, the relay patterns 38 in the Comparative Example are omitted from each of the six semiconductor units 30. As a result, an advantage is obtained in which it is possible to expand a region that can be used for installation of the semiconductor chips 35 in each of the six semiconductor units 30.

### B: Second Embodiment

A Second Embodiment will now be described. In the descriptions of the following embodiments, elements having the same functions as in the First Embodiment are denoted by the same reference numerals used for like elements in the description of the First Embodiment, and detailed description thereof is omitted, as appropriate.

In the Second Embodiment, a configuration of the wiring substrate 50a and a configuration of the wiring substrate 50b are different from those of the First Embodiment. In the Second Embodiment, elements other than the wiring substrate 50a and the wiring substrate 50b are the same as those in the First Embodiment. Thus, the Second Embodiment provides the same effects as those provided by the First Embodiment.

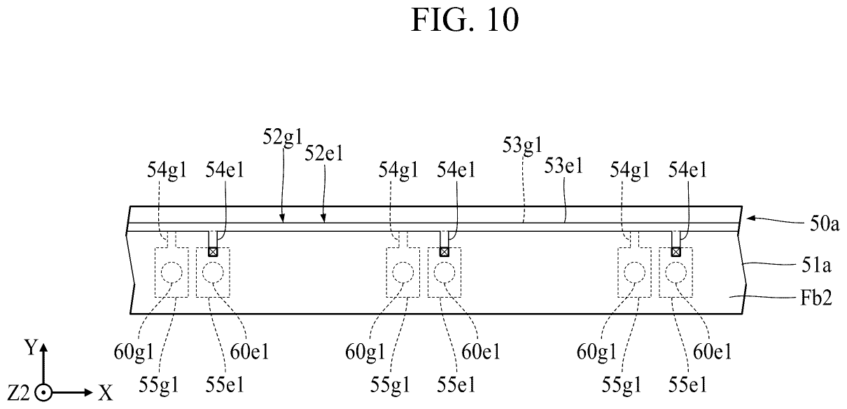

FIG. 10 is a plan view of the wiring substrate 50a according to the Second Embodiment. In the First Embodiment, as shown in FIG. 4, a configuration is described in which a location of the extending portion 53g1 of the line 52g1 in the direction of the Y-axis is different from a location of the extending portion 53e1 of the line 52e1 in the direction of the Y-axis. In other words, in plan view, the extending portion 53g1 and the extending portion 53e1 are separate from each other.

In contrast to the First Embodiment, in the wiring substrate 50a according to the Second Embodiment, as shown in FIG. 10, in plan view, the extending portion 53g1 of the line 52g1 and the extending portion 53e1 of the line 52e1 overlap one over the other. In other words, in the Second Embodiment, a location of the extending portion 53g1 in the direction of the Y-axis is the same as a location of the extending portion 53e1 in the direction of the Y-axis. In other words, the Second Embodiment includes a configuration in which the extending portion 53g1 and the extending portion 53e1 face each other across the insulated substrate 51a.

As described above, in the Second Embodiment, in plan view, the extending portion 53g1 connected to the control electrode G of each of the semiconductor chips 35b overlaps with the extending portion 53e1 connected to the second electrode E2 of each of the semiconductor chips 35b. Thus, compared to a configuration in which the extending portion 53g1 and the extending portion 53e1 are separate from each other in plan view, it is possible to reduce inductive components caused by the line 52g1 and the line 52e1.

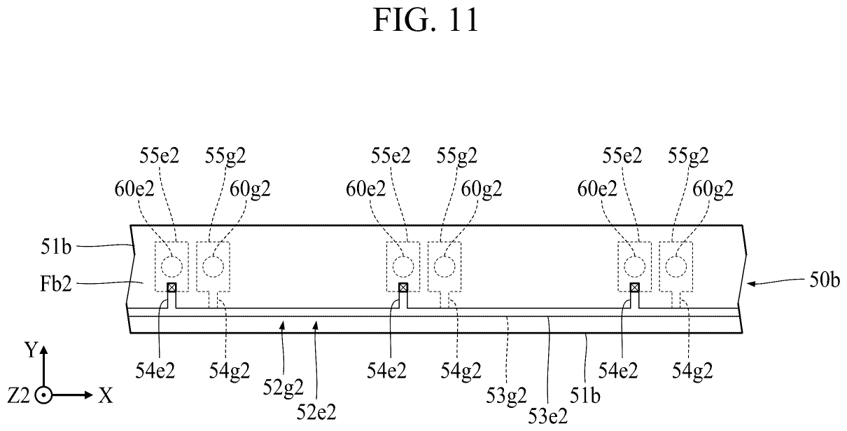

FIG. 11 is a plan view of the wiring substrate 50b according to the Second Embodiment. In the First Embodiment, as shown in FIG. 6, a configuration is described in which a location of the extending portion 53g2 of the line 52g2 in the direction of the Y-axis is different from a location of the extending portion 53e2 of the line 52e2 in the direction of the Y-axis. In other words, in plan view, the extending portion 53g2 and the extending portion 53e2 are separate from each other.

In contrast to the First Embodiment, in the wiring substrate 50b according to the Second Embodiment, as shown in FIG. 11, in plan view, the extending portion 53g2 of the line 52g2 and the extending portion 53e2 of the line 52e2 overlap one over the other. In other words, in the Second Embodiment, a location of the extending portion 53g2 in the direction of the Y-axis is the same as a location of the extending portion 53e2 in the direction of the Y-axis. In other words, the Second Embodiment includes a configuration in which the extending portion 53g2 and the extending portion 53e2 face each other across the insulated substrate 51b.

As described above, in the Second Embodiment, in plan view, the extending portion 53g2 connected to the control electrode G of each of the semiconductor chips 35a overlaps with the extending portion 53e2 connected to the second electrode E2 of each of the semiconductor chips 35a. Thus, compared to a configuration in which the extending portion 53g2 and the extending portion 53e2 are separate from each other in plan view, it is possible to reduce inductive components caused by the line 52g2 and the line 52e2.

### C: Third Embodiment

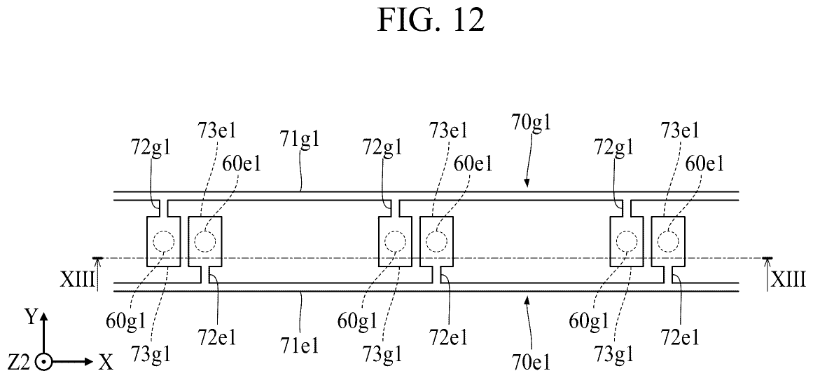

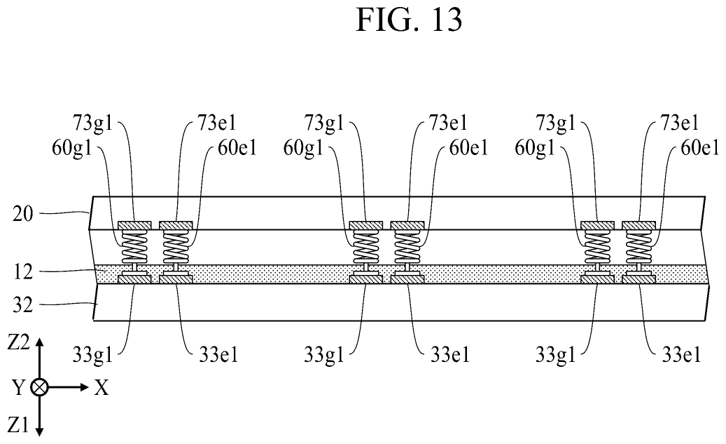

FIG. 12 according to a Third Embodiment is a plan view explaining connection of the conductive pattern 33g1 and the conductive pattern 33e1. FIG. 13 is a cross section taken along line XIII-XIII shown in FIG. 12.

As shown in FIG. 12 and FIG. 13, in the Third Embodiment, the wiring substrate 50a according to the First Embodiment is replaced with a conductive member 70g1 and a conductive member 70e1. The conductive member 70g1 and the conductive member 70e1 are each a plate-shaped conductor (lead frame) made of a low-resistance conductive material such as a copper material or an alloy of copper. The conductive member 70g1 and the conductive member 70e1 may be plated with a nickel material, a nickel-phosphorus alloy, or a nickel-boron alloy, for example,

The conductive member 70g1 and the conductive member 70e1 are disposed on the lower surface of the lid 20. For example, the conductive member 70g1 and the conductive member 70e1 are formed by insert molding to be disposed on the lid 20. Alternatively, after the lid 20 being formed, the conductive member 70g1 and the conductive member 70e1 may be disposed on the lid 20.

As shown in FIG. 12, the conductive member 70g1 includes an extending portion 71g1, six branch portions 72g1, and six connecting terminals 73g1. The extending portion 71g1 is a portion that extends in the direction of the X-axis. The six connecting terminals 73g1 are aligned with, and are spaced apart from, one another in the direction of the X-axis. The six branch portions 72g1 are portions for coupling the extending portion 71g1 and the six connecting terminals 73g1.

The conductive member 70e1 includes an extending portion 71e1, six branch portions 72e1, and six connecting terminals 73e1. The extending portion 71e1 is a portion that extends in the direction of the X-axis. The six connecting terminals 73e1 are aligned with, and are spaced apart from, one another in the direction of the X-axis. The six branch portions 72e1 are portions for coupling the extending portion 71e1 and the connecting terminals 73e1.

As shown in FIG. 12, the extending portion 71g1 and the extending portion 71e1 extend in parallel to, and are spaced apart from, each other. In plan view, between the extending portion 71g1 and the extending portion 71e1, the connecting terminals 73g1 and the connecting terminals 73e1 are alternately aligned with one another along the X-axis.

As shown in FIG. 13, each of the connecting terminals 73g1 of the conductive member 70g1 is electrically connected to a conductive pattern 33g1 of a corresponding semiconductor unit 30 via a connecting portion 60g1. Similarly, each of the connecting terminals 73e1 of the conductive member 70e1 is electrically connected to a conductive pattern 33e1 of a corresponding semiconductor unit 30 via a connecting portion 60e1. In the Third Embodiment, the connecting portion 60g1 and the connecting portion 60e1 have the same configuration as those in the First Embodiment.

In the Third Embodiment, the plate-shaped conductive member 70g1 and the plate-shaped conductive member 70e1 that are disposed on the lid 20 are connected to the six semiconductor units 30. Thus, compared to a configuration in which the wiring substrate 50a is connected to the six semiconductor units 30, it is possible to simplify a configuration of the semiconductor device 100.

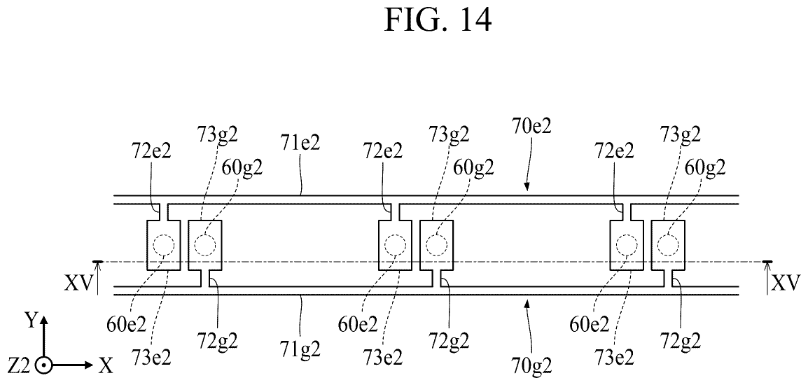

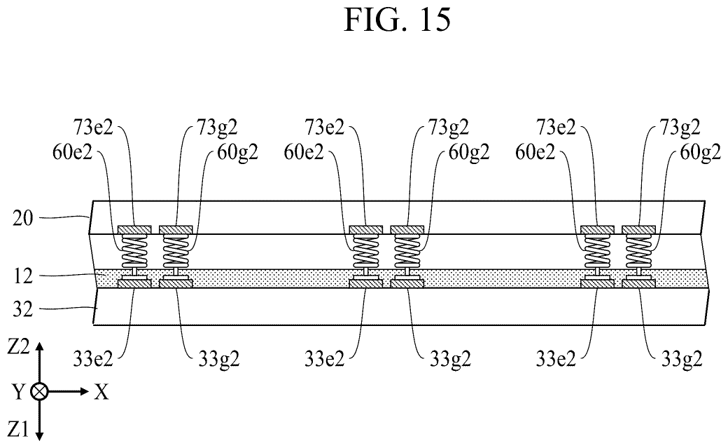

FIG. 14 according to the Third Embodiment is a plan view explaining connection of the conductive pattern 33g2 and the conductive pattern 33e2. FIG. 15 is a cross section taken along line XV-XV shown in FIG. 14. In the Third Embodiment, the wiring substrate 50b according to the First Embodiment is replaced with a conductive member 70g2 and a conductive member 70e2. The conductive member 70g2 and the conductive member 70e2 are each a plate-shaped conductor (lead frame) made of a low-resistance conductive material such as a copper material or an alloy of copper. The conductive member 70g2 and the conductive member 70e2 may be plated with a nickel material, a nickel-phosphorus alloy, or a nickel-boron alloy, for example,

The conductive member 70g2 and the conductive member 70e2 are disposed on the lower surface of the lid 20. For example, the conductive member 70g2 and the conductive member 70e2 are formed by insert molding to be disposed on the lid 20. Alternatively, after the lid 20 is formed, the conductive member 70g2 and the conductive member 70e2 may be disposed on the lid 20.

The conductive member 70g2 is electrically connected to conductive patterns 33g2 of the six semiconductor units 30 via the connecting portions 60g2. Similarly, the conductive member 70e2 is electrically connected to conductive patterns 33e2 of the six semiconductor units 30 via the connecting portions 60e2. In the Third Embodiment, the connecting portions 60g2 and the connecting portions 60e2 have the same configuration as those in the First Embodiment.

In the Third Embodiment, the plate-shaped conductive member 70g2 and the plate-shaped conductive member 70e2 that are disposed on the lid 20 are connected to the six semiconductor units 30. Thus, compared to a configuration in which the wiring substrate 50b is connected to the six semiconductor units 30, it is possible to simplify a configuration of the semiconductor device 100.

In the First Embodiment and the Second Embodiment, the wiring substrate 50a and the wiring substrate 50b are disposed. Thus, there is an advantage in that it is possible to readily ensure flexibility in designing the respective lines 52 (52g1, 52e1, 52g2, and 52e2). For example, as shown in the Second Embodiment, a configuration can be adopted in which the extending portion 53g1 of the line 52g1 and the extending portion 53e1 of the line 52e1 overlap one over the other in a plan view, or alternatively, a configuration can be adopted in which the extending portion 53g2 of the line 52g2 and the extending portion 53e2 of the line 52e2 overlap one over the other in plan view.

### D: Modifications

Specific modifications that may be applied to each of the embodiments described above are described below. Two or more modifications freely selected from the following modifications may be combined as long as no conflict arises from such combination.

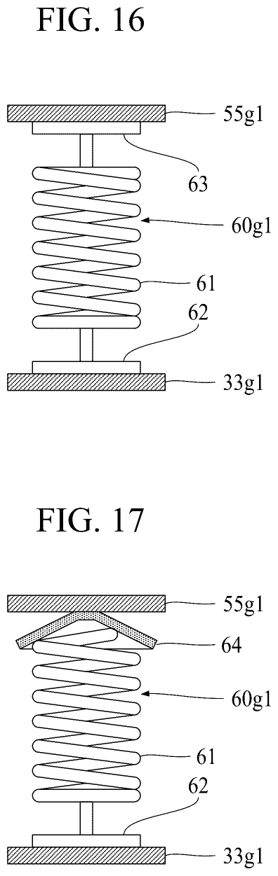

(1) The configuration of the connecting portion 60 is not limited to the example in each of the embodiments described above. For example, as shown in FIG. 16, the connecting portion 60 may include a terminal portion 63 in addition to the elastic body 61 and the terminal portion 62 included in the respective embodiments described above. The terminal portion 63 is a terminal connected to the upper end of the elastic body 61. In a state in which the elastic body 61 is compressed, the terminal portion 63 is pressed against the connecting terminal 55g1. The connecting portion 60 shown in FIG. 16 may be used in the Second Embodiment and the Third Embodiment.

As shown in FIG. 17, the connecting portion 60 may include a holder 64 in addition to the elastic body 61 and the terminal portion 62 included in the First Embodiment. The holder 64 is a structure disposed on the connecting terminal 55g1. A lower surface of the holder 64 is provided with a recess. The upper end of the elastic body 61 is accommodated in the recess. According to the above configuration, the holder 64 accommodates the upper end of the elastic body 61. Thus, it is possible to substantially prevent displacement of the upper end of the elastic body 61. In other words, it is possible to reduce probability of displacement of the upper end of the elastic body 61 in a direction intersecting the Z-axis.

(2) In each embodiment described above, a configuration is described in which the semiconductor chip 35 is an IGBT. However, the semiconductor chip 35 is not limited to an IGBT. For example, the semiconductor chip 35 may be an electronic element such as a reverse conducting insulated gate bipolar transistor (RC-IGBT) or a Schottky Barrier Diode (SBD) in each of which the semiconductor chip 35 and the semiconductor chip 36 are integrally formed. The semiconductor chip 35 may be a metal oxide semiconductor field effect transistor (MOSFET) having a semiconductor layer made of a silicon (Si) material or of a silicon carbide (SiC) material. In a configuration in which the semiconductor chip 35 is constituted of a MOSFET, the first electrode E1 is a drain electrode, and the second electrode E2 is a source electrode.

(3) The denotation “n-th” (n is a natural number) is used in this disclosure for convenience and as mere formal labels for distinguishing different elements from each other, and such a denotation has no substantial inherent meaning. Thus, denotation of a position of an element or an order of production of an element as “n-th” is not limited to a narrow literal interpretation, and a position and an order of an element and the like are broadly interpreted.

### E: Supplemental Notes

The following configurations are derivable from the foregoing embodiments.

A semiconductor device according to one aspect (first aspect) of this disclosure includes a plurality of semiconductor units connected in parallel to each other; a housing for surrounding the plurality of semiconductor units; a lid disposed on the housing, the lid facing the plurality of semiconductor units; a wiring portion disposed on the lid; and a plurality of connecting portions, each corresponding to a semiconductor unit of the plurality of semiconductor units, in which each of the plurality of semiconductor units includes a first conductor; a semiconductor chip disposed on the first conductor; and a second conductor connected to the semiconductor chip so as to control the semiconductor chip, and in which a connecting portion that is any one of the plurality of connecting portions is interposed between the wiring portion and a second conductor included in a semiconductor unit corresponding to the connecting portion among the plurality of semiconductor units, the connecting portion electrically connecting the wiring portion and the second conductor included in the semiconductor unit corresponding to the connecting portion to each other.

According to this aspect, the second conductor of each of the plurality of semiconductor units is electrically connected to the wiring portion disposed on the lid. Thus, compared to a configuration in which each of the plurality of semiconductor units is provided with conductive patterns (wiring lines) connected to other conductive patterns, it is possible to reduce a planar size of each of the plurality of semiconductor units. In addition, the conductive patterns for connecting the second conductors of the plurality of semiconductor units to each other are omitted from each of the plurality of semiconductor units. As a result, an advantage is obtained in which it is possible to expand a region that can be used for installation of the semiconductor chip in each of the plurality of semiconductor units.

In a specific example (second aspect) of the first aspect, the connecting portion includes an elastic body compressed and disposed between the wiring portion and the second conductor included in the semiconductor unit corresponding to the connecting portion. According to this aspect, in an easy step in which the lid compresses the elastic body in the course of disposing the lid on the housing, the connecting portion can reliably electrically connect the second conductor and the wiring portion to each other.

In a specific example (third aspect) of the first aspect or of the second aspect, the semiconductor chip includes a control electrode, the second conductor includes a first conductive pattern electrically connected to the control electrode, the wiring portion includes a first line, and the plurality of connecting portions include a first connecting portion electrically connecting the first line to a first conductive pattern included in a semiconductor unit corresponding to the first connecting portion among the plurality of semiconductor units. According to this aspect, it is possible to electrically connect the control electrode of the semiconductor chip of each of the plurality of semiconductor units to the first line via the first conductive pattern and the first connecting portion.

In a specific example (fourth aspect) of the third aspect, the semiconductor chip includes a first electrode joined to a mounting substrate; and a second electrode opposite to the first electrode, the second conductor includes a second conductive pattern electrically connected to the second electrode, the wiring portion includes a second line, and the plurality of connecting portions include a second connecting portion electrically connecting the second line to a second conductive pattern included in a semiconductor unit corresponding to the second connecting portion among the plurality of semiconductor units. According to this aspect, it is possible to electrically connect the auxiliary emitter terminal of the semiconductor chip of each of the plurality of semiconductor units to the second line via the second conductive pattern and the second connecting portion.

In a specific example (fifth aspect) of the fourth aspect, the first line includes a first extending portion extending in a direction in which the plurality of semiconductor units are aligned with each other, the second line includes a second extending portion extending in the direction in which the plurality of semiconductor units are aligned with each other, and the first extending portion and the second extending portion overlap one over the other in plan view. According to this aspect, in plan view, the first extending portion connected to the control electrode of each of the plurality of semiconductor chips overlaps with the second extending portion connected to the second electrode of each of the plurality of semiconductor chips. Thus, compared to a configuration in which the first extending portion and the second extending portion are separate from each other in plan view, it is possible to reduce inductive components caused by the first line and the second line.

In a specific example (sixth aspect) of the fifth aspect, the semiconductor device further includes an insulated substrate disposed on the lid, the insulated substrate includes a first surface; and a second surface opposite to the first surface, the first extending portion is disposed on the first surface, and the second extending portion is disposed on the second surface. According to this aspect, by a simple configuration in which the insulated substrate includes both the first surface provided with the first extending portion and the second surface provided with the second extending portion, the first extending portion and the second extending portion can overlap one over the other in plan view.

In a specific example (seventh aspect) of any one of the first to fifth aspects, the semiconductor device further includes a wiring substrate disposed on the lid, and the wiring substrate includes an insulated substrate; and the wiring portion disposed on the insulated substrate. According to this aspect, the lid is provided with the wiring substrate that includes the insulated substrate and the wiring portion. Thus, it is possible to sufficiently ensure flexibility in designing the wiring portion.

In a specific example (eighth aspect) of any one of the first to fifth aspects, the wiring portion is constituted of a plate-shaped conductive member. According to this aspect, since the wiring portion is constituted of the plate-shaped conductive member, it is possible to simplify a configuration of the semiconductor device.

### DESCRIPTION OF REFERENCE SIGNS

100 . . . semiconductor device, 10 . . . housing, 12 . . . encapsulant, 20 . . . lid, 30 . . . semiconductor unit, 31 . . . mounting substrate, 32 . . . insulated substrate, 33a, 33b, 33c, 33g1, 33e1, 33g2, 33e2 . . . conductive pattern, 35, 35a, 35b . . . semiconductor chip, 36, 36a, 36b . . . semiconductor chip, 50a, 50b . . . wiring substrate, 51a, 51b . . . insulated substrate, 52g1, 52e1, 52g2, 52e2 . . . line, 53g1, 53e1, 53g2, 53e2 . . . extending portion, 54g1, 54e1, 54g2, 54e2 . . . branch portion, 55g1, 55e1, 55g2, 55e2 . . . connecting terminal, 60g1, 60e1, 60g2, 60e2 . . . connecting portion, 61 . . . elastic body, 62, 63 . . . terminal portion, 70g1, 70e1, 70g2, 70e2 . . . conductive member, 71g1, 71e1, 71g2, 71e2 . . . extending portion, 72g1, 72e1, 72g2, 72e2 . . . branch portion, 73g1, 73e1, 73g2, 73e2 . . . connecting terminal.

What is claimed is:

1. A semiconductor device comprising:
a plurality of semiconductor units connected in parallel to each other;
a housing for surrounding the plurality of semiconductor units;
a lid disposed on the housing, the lid facing the plurality of semiconductor units;
a wiring portion disposed on the lid; and
a plurality of connecting portions, each corresponding to a semiconductor unit of the plurality of semiconductor units,
wherein each of the plurality of semiconductor units includes:
a first conductor;
a semiconductor chip disposed on the first conductor; and
a second conductor connected to the semiconductor chip so as to control the semiconductor chip, and
wherein a connecting portion that is any one of the plurality of connecting portions is interposed between the wiring portion and a second conductor included in a semiconductor unit corresponding to the connecting portion among the plurality of semiconductor units, the connecting portion electrically connecting the wiring portion and the second conductor included in the semiconductor unit corresponding to the connecting portion to each other.

2. The semiconductor device according to claim 1, wherein the connecting portion includes an elastic body compressed and disposed between the wiring portion and the second conductor included in the semiconductor unit corresponding to the connecting portion.

3. The semiconductor device according to claim 1,
wherein the semiconductor chip includes a control electrode,
wherein the second conductor includes a first conductive pattern electrically connected to the control electrode,
wherein the wiring portion includes a first line, and
wherein the plurality of connecting portions include a first connecting portion electrically connecting the first line to a first conductive pattern included in a semiconductor unit corresponding to the first connecting portion among the plurality of semiconductor units.

4. The semiconductor device according to claim 3,
wherein the semiconductor chip includes:
a first electrode joined to a mounting substrate; and
a second electrode opposite to the first electrode,
wherein the second conductor includes a second conductive pattern electrically connected to the second electrode,
wherein the wiring portion includes a second line, and
wherein the plurality of connecting portions include a second connecting portion electrically connecting the second line to a second conductive pattern included in a semiconductor unit corresponding to the second connecting portion among the plurality of semiconductor units.

5. The semiconductor device according to claim 4,
wherein the first line includes a first extending portion extending in a direction in which the plurality of semiconductor units are aligned with each other,
wherein the second line includes a second extending portion extending in the direction in which the plurality of semiconductor units are aligned with each other, and
wherein the first extending portion and the second extending portion overlap one over the other in plan view.

6. The semiconductor device according to claim 5,
further comprising an insulated substrate disposed on the lid,
wherein the insulated substrate includes:
a first surface; and
a second surface opposite to the first surface,
wherein the first extending portion is disposed on the first surface, and
wherein the second extending portion is disposed on the second surface.

7. The semiconductor device according to claim 1,
further comprising a wiring substrate disposed on the lid,
wherein the wiring substrate includes:
an insulated substrate; and
the wiring portion disposed on the insulated substrate.

8. The semiconductor device according to claim 1, wherein the wiring portion is constituted of a plate-shaped conductive member.
